(19) United States
(12) Patent Application Publication
(10) Pub. No.: US 2014/0175158 A1
(43) Pub. Date: Jun. 26, 2014

(54) METHOD FOR MANUFACTURING LIGHT EMITTING DIODE PACKAGE

(71) Applicant: HON HAI PRECISION INDUSTRY CO., LTD., New Taipei (TW)

(72) Inventor: CHIH-CHEN LAI, New Taipei (TW)

(21) Appl. No.: 13/926,113

(22) Filed: Jun. 25, 2013

(30) Foreign Application Priority Data
Dec. 24, 2012 (TW) 101149577

(51) Int. Cl. H01L 33/00

(52) U.S. Cl. CPC H01L 33/005
USPC 228/102

(57) ABSTRACT

A method for manufacturing an LED package includes following steps: providing a eutectic bonding apparatus comprising a heating device, a supporting platform located in the heating device, and a nozzle; providing a resistance measuring device comprising a probe, an electrical power, and a controlling unit; providing an LED chip; providing a substrate and positioning the substrate on the supporting platform of the eutectic bonding apparatus; moving the nozzle to catch the LED chip onto the substrate; and heating the substrate and the LED chip to form a eutectic bonding process. The probe of the resistance measuring device is electrically connected to the LED chip, a total resistance of the LED chip and the substrate is measured by the resistance measuring device in real-time, when the total resistance is equal to a predetermined value, the heating device is ordered to stop heating by the controlling unit.

### BACKGROUND

1. Technical Field

The disclosure generally relates to a method for manufacturing a light emitting diode (LED) package.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

Nowadays, in a method of manufacturing an LED package, an LED chip could be fixed on a substrate in a manner of eutectic bonding. Eutectic bonding, also referred to as eutectic soldering, describes a wafer bonding technique with an intermediate metal layer that can produce a eutectic system. Eutectic alloys are deposited on the LED chip and the substrate by sputtering, dual source evaporation or electroplating. It also can be formed by diffusion reactions of pure materials and subsequently melting of the eutectic composition. Those eutectic metals are alloys that transform directly from solid to liquid state, or vice versa from liquid to solid state, at a specific composition and temperature without passing a two-phase equilibrium, i.e. liquid and solid state. The fact that the eutectic temperature can be much lower than the melting temperature of the two or more pure elements can be important in eutectic bonding. However, in the process of eutectic bonding, it is hard to control the time of heating accurately, if the time is too long, it may cause waste of operation waiting and the cost arising; otherwise the bonding is not strong enough.

What is needed, therefore, is a method for manufacturing an LED package to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a flow chart of a method for manufacturing an LED package in accordance with an embodiment of the present disclosure.

FIG. 2 shows a step 105 of the method of FIG. 1.

FIG. 3 shows a step 107 of the method of FIG. 1.

FIG. 4 is a schematic view of a relationship of total resistance of an LED chip and a substrate the LED chip attached onto relative to eutectic bonding degree between the LED chip and the substrate.

FIG. 5 is an isometric, schematic view of the LED package manufactured by the method of FIG. 1.

### DETAILED DESCRIPTION

Embodiments of a lighting device and a method for manufacturing an LED package will now be described in detail below and with reference to the drawings.

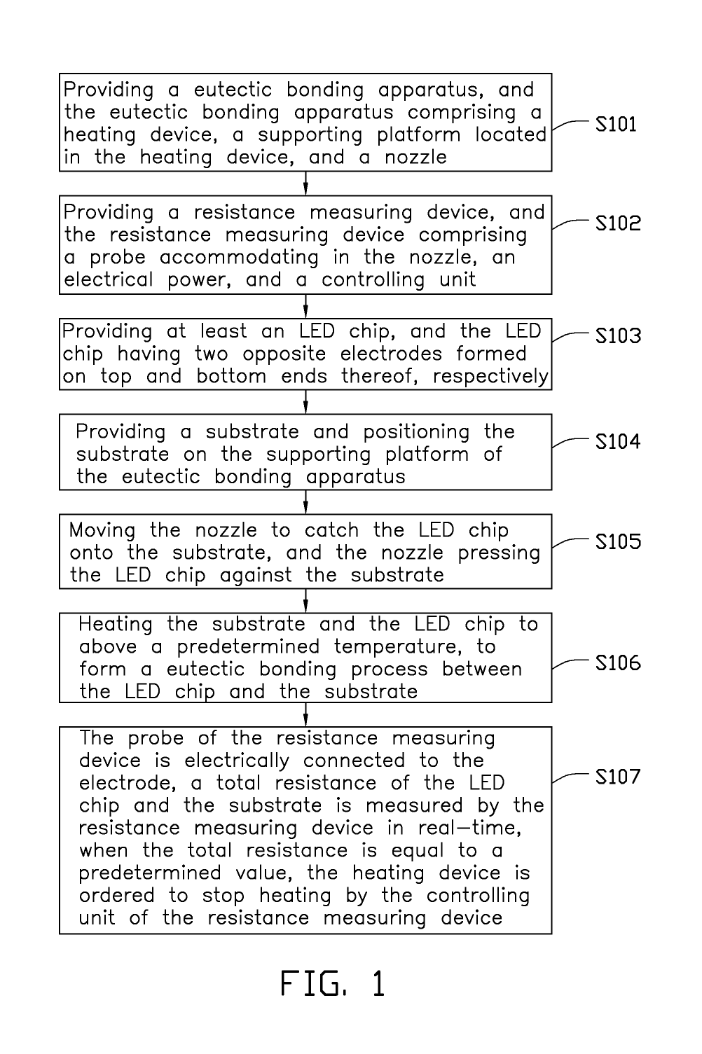

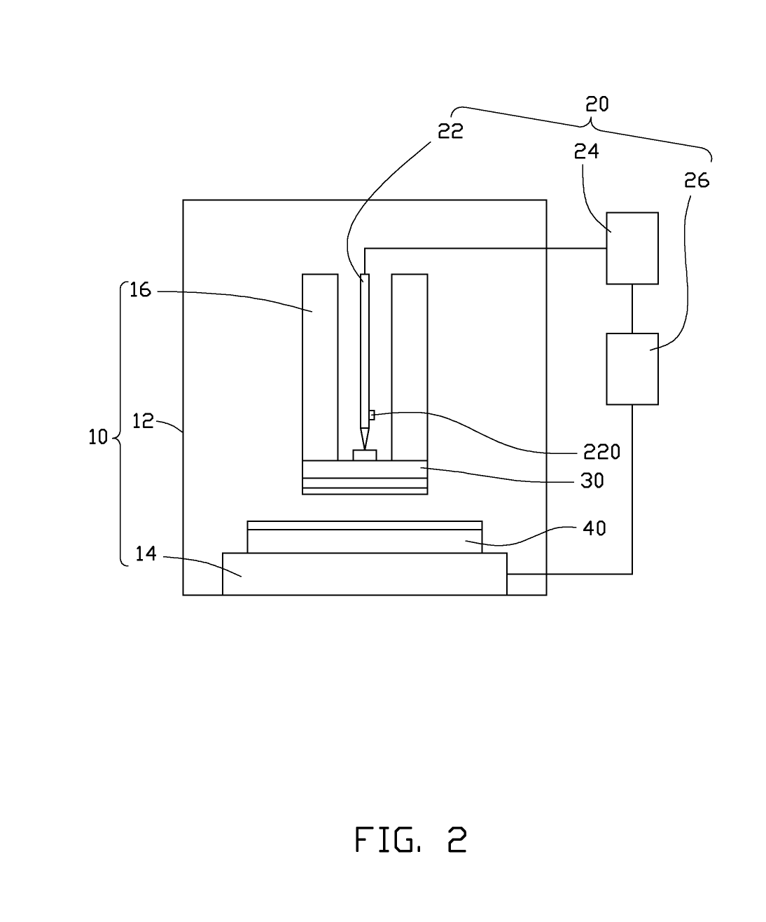

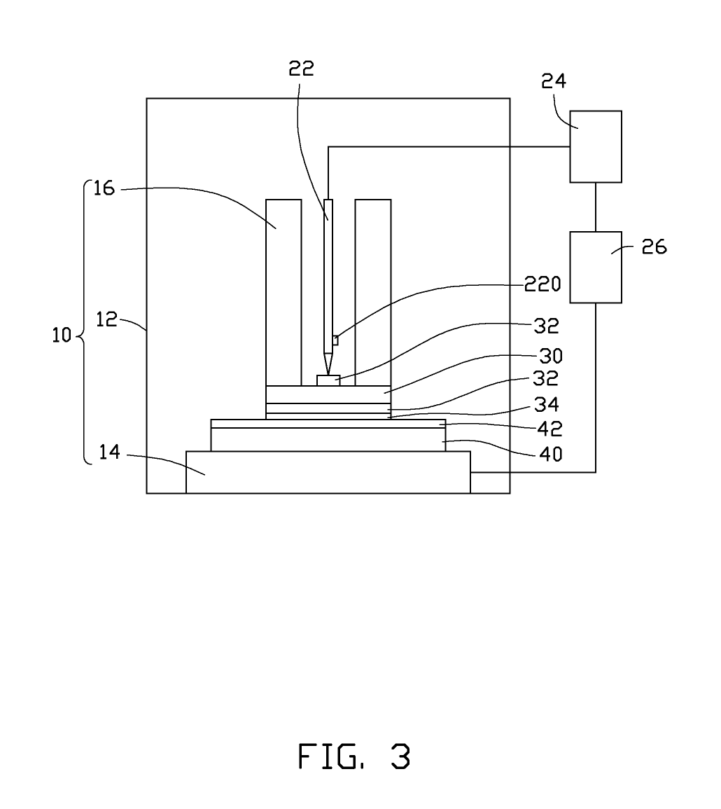

Referring to FIGS. 1-5, a method for manufacturing an LED package 100 in accordance with an embodiment is provided. The method for manufacturing the LED package 100 includes following steps.

Step 101, a eutectic bonding apparatus 10 is provided. The eutectic bonding apparatus 10 includes a heating device 12, a supporting platform 14 located in the heating device 12, and a nozzle 16.

Step 102, a resistance measuring device 20 is provided. The resistance measuring device 20 includes a probe 22 accommodating in the nozzle 16, an electrical power 24, and a controlling unit 26.

Step 103, at least an LED chip 30 is provided. The LED chip 30 has two opposite electrodes 32 formed on top and bottom ends thereof, respectively.

Step 104, a substrate 40 is provided. The substrate 40 is positioned on the supporting platform 14 of the eutectic bonding apparatus 10.

Step 105, the nozzle 16 catches the LED chip 30 onto the substrate 40. The nozzle 16 presses the LED chip 30 against the substrate 40.

Step 106, the LED chip 30 and the substrate 40 are heated over a predetermined temperature, about 370° C., to form a eutectic bonding process between the LED chip 30 and the substrate 40.

Step 107, the probe 22 of the resistance measuring device 20 is electrically connected to the electrode 32, a total resistance A of the LED chip 30 and the substrate 40 is measured by the resistance measuring device 20 in real-time, when the total resistance A is equal to a predetermined value B, the heating device 12 is ordered to stop heating by the controlling unit 26 of the resistance measuring device 20, and the LED chip 30 with the substrate 40 are taken out of the eutectic bonding apparatus 10.

The probe 22 is made of tungsten carbide, steel or alloy. The probe 22 is further provided with an automatic sensor 220. The automatic sensor 220 is configured for automatically sensing a distance between the probe 22 and the electrode 32 of the LED chip 30 and allowing a free end of the probe 22 to reach the electrode 32 slowly, thereby avoiding a hitting accident therebetween.

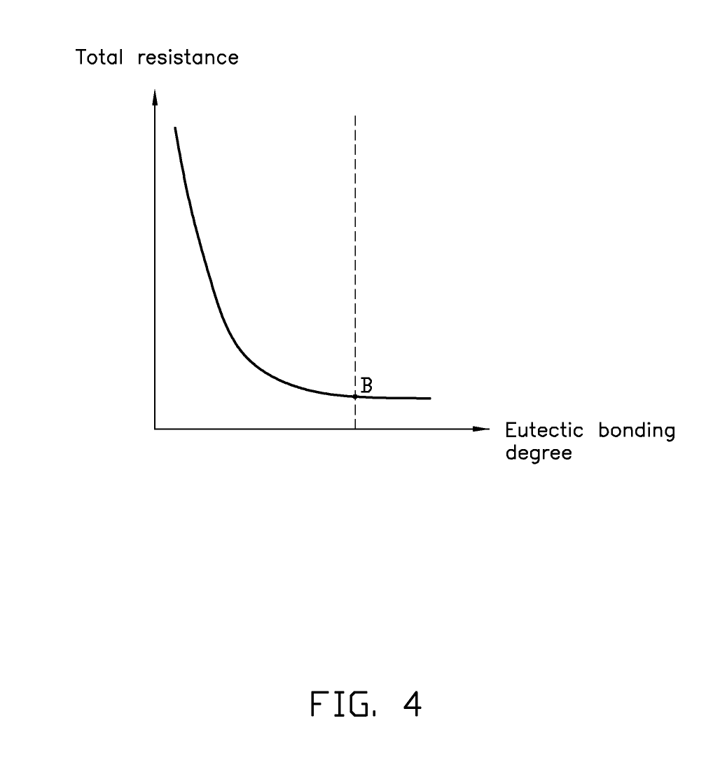

In step 107, the longer the LED chip 30 and the substrate 40 are heated in the eutectic bonding process, the more the eutectic bonding degree between the LED chip 30 and the substrate 40 is achieved. However, referring to FIG. 4 again, after the eutectic bonding degree between the LED chip 30 and the substrate 40 achieves to a certain level, the value of the total resistance is almost invariable, and that is to say, the eutectic bonding degree at the certain level is good enough. The predetermined value B could be an average value got in a plurality of experiments. The controlling unit 26 of the resistance measuring device 20 constantly comparing the total resistance A of the LED chip 30 and the substrate 40 with the predetermined value B, when they are matched, the heating device 12 is ordered to stop heating by the controlling unit 26, and the eutectic bonding process between the LED chip 30 and the substrate 40 ends.

The LED chip 30 is made of aluminum indium gallium phosphide, such as AlₓIn_{y}Ga_{(1-x-y)}P (0≦X≦1, 0≦Y≦1, X=Y≦1), aluminum indium gallium arsenide, such as AlₓIn_{y}Ga_{(1-x-y)}As (0≦X≦1, 0≦Y≦1, X=Y≦1), or aluminum indium gallium nitride, such as AlₓIn_{y}Ga_{(1-x-y)}N (0≦X≦1, 0≦Y≦1, X=Y≦1). The LED chip 30 further includes a first metal layer 34 formed on a bottom thereof. The first metal layer 34 is made of Au, Sn, In, AL, Ag, Bi, Be, Cu or alloy thereof.

The substrate 40 is made of Si, Al or Cu. The substrate 40 further includes a second metal layer 42 formed on a top thereof. The second metal layer 42 is made of Au, Sn, In, AL, Ag, Bi, Be, Cu or alloy thereof. The eutectic bonding process is occurred between the first metal layer 34 and the second metal layer 42.

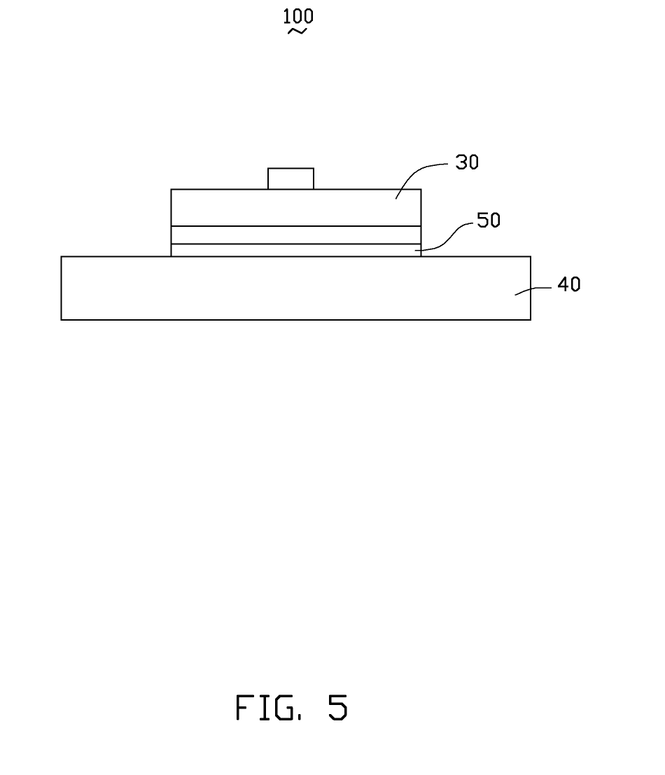

Referring to FIG. 5 again, the LED package 100 is manufactured by the method of the embodiment of the present disclosure, the LED package 100 includes a substrate 40, an LED chip 30 mounted on the substrate 40, and a eutectic fusion layer 50 formed between the LED chip 30 and the substrate 40.

It can be understood that, the resistance measuring device 20 could be accommodated in the eutectic bonding apparatus 10, and act as a functional part of the eutectic bonding apparatus 10 integrally.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for manufacturing a light emitting diode (LED) package, comprising following steps:
providing a eutectic bonding apparatus, and the eutectic bonding apparatus comprising a heating device, a supporting platform located in the heating device, and a nozzle;
providing a resistance measuring device, and the resistance measuring device comprising a probe accommodating in the nozzle, an electrical power, and a controlling unit;
providing at least an LED chip, and the LED chip having two opposite electrodes formed on top and bottom ends thereof, respectively;
providing a substrate and positioning the substrate on the supporting platform of the eutectic bonding apparatus;
moving the nozzle to catch the LED chip onto the substrate, and the nozzle pressing the LED chip against the substrate; and
heating the substrate and the LED chip to above a predetermined temperature, to form a eutectic bonding process between the LED chip and the substrate;
wherein the probe of the resistance measuring device is electrically connected to the electrode, a total resistance of the LED chip and the substrate is measured by the resistance measuring device in real-time, when the total resistance is equal to a predetermined value, the heating device is ordered to stop heating by the controlling unit of the resistance measuring device.

2. The method of claim 1, wherein the LED chip further comprises a first metal layer formed on a bottom thereof, and the first metal layer is made of Au, Sn, In, AL, Ag, Bi, Be, Cu or alloy thereof.

3. The method of claim 1, wherein the substrate further comprises a second metal layer formed on a top thereof, and the second metal layer is made of Au, Sn, In, AL, Ag, Bi, Be, Cu or alloy thereof.

4. The method of claim 1, wherein the LED chip is made of aluminum indium gallium phosphide, such as AlₓIn_{y}Ga_{(1-x-y})P (0≦X≦1, 0≦Y≦1, X=Y≦1).

5. The method of claim 1, wherein the LED chip is made of aluminum indium gallium arsenide, such as AlₓIn_{y}Ga_{(1-x-y)}As (0≦X≦1, 0≦Y≦1, X=Y≦1).

6. The method of claim 1, wherein the LED chip is made of aluminum indium gallium nitride, such as AlₓIn_{y}Ga_{(1-x-y)}N (0≦X≦1, 0≦Y≦1, X=Y≦1).

7. The method of claim 1, wherein the probe is further provided with an automatic sensor, and the automatic sensor is configured for automatically sensing a distance between the probe and the electrode of the LED chip and allowing a free end of the probe to reach the electrode slowly, thereby avoiding a hitting accident therebetween.

8. The method of claim 1, wherein the probe is made of tungsten carbide, steel or alloy.

9. The method of claim 1, wherein the substrate is made of Si, Al or Cu.

10. The method of claim 1, wherein in step of heating the substrate and the LED chip, the predetermined temperature is 370° C.

11. A method for manufacturing an LED package, comprising following steps:
providing a eutectic bonding apparatus, and the eutectic bonding apparatus comprising a heating device, a supporting platform located in the heating device, a nozzle, a probe and a controlling unit;
providing an LED chip;
providing a substrate and positioning the substrate on the supporting platform of the eutectic bonding apparatus;
moving the nozzle to catch the LED chip onto the substrate, and the nozzle pressing the LED chip against the substrate; and
heating the substrate and the LED chip to above a predetermined temperature, to form a eutectic bonding process between the LED chip and the substrate;
wherein the probe is electrically connected to the LED chip, a total resistance of the LED chip and the substrate is measured by the controlling unit in real-time, when the total resistance is equal to a predetermined value, the heating device is ordered to stop heating by the controlling unit.

12. The method of claim 11, wherein the LED chip further comprises a first metal layer formed on a bottom thereof, and the first metal layer is made of Au, Sn, In, AL, Ag, Bi, Be, Cu or alloy thereof.

13. The method of claim 11, wherein the substrate further comprises a second metal layer formed on a top thereof, and the second metal layer is made of Au, Sn, In, AL, Ag, Bi, Be, Cu or alloy thereof.

14. The method of claim 11, wherein the LED chip is made of aluminum indium gallium phosphide, such as AlₓIn_{y}Ga_{(1-x-y)}P (0≦X≦1, 0≦Y≦1, X=Y≦1).

15. The method of claim 11, wherein the LED chip is made of aluminum indium gallium arsenide, such as AlₓIn_{y}Ga_{(1-x-y)}As (0≦X≦1, 0≦Y≦1, X=Y≦1).

16. The method of claim 11, wherein the LED chip is made of aluminum indium gallium nitride, such as AlₓIn_{y}Ga_{(1-x-y)}N (0≦X≦1, 0≦Y≦1, X=Y≦1).

17. The method of claim 11, wherein the probe is further provided with an automatic sensor, and the automatic sensor is configured for automatically sensing a distance between the probe and the LED chip and allowing a free end of the probe to reach the LED chip slowly, thereby avoiding a hitting accident therebetween.

18. The method of claim 11, wherein the probe is made of tungsten carbide, steel or alloy.

19. The method of claim 11, wherein the substrate is made of Si, Al or Cu.

20. The method of claim 11, wherein in step of heating the substrate and the LED chip, the predetermined temperature is 370° C.
